(19) United States
(12) Patent Application Publication
(10) Pub. No.: US 2011/0291078 A1
(43) Pub. Date: Dec. 1, 2011

(54) OTFT USING PAPER AS SUBSTRATE AND SILK PROTEIN AS INSULATING MATERIAL AND METHOD FOR MANUFACTURING THE SAME

(76) Inventors: Jenn-Chang HWANG, Hsinchu (TW); Chung Hwa Wang, Hsinchu (TW); Chao Ying Hsieh, Hsinchu (TW)

(21) Appl. No.: 12/842,511

(22) Filed: Jul. 23, 2010

(30) Foreign Application Priority Data
May 28, 2010 (TW) 099117223

(51) Int. Cl. H01L 51/10; H01L 51/40

(52) U.S. Cl. 257/40; 438/99; 257/E51.006

(57) ABSTRACT

An organic thin film transistor (OTFT) using paper as a substrate and silk protein as an insulating material and methods for manufacturing the same are disclosed. The OTFT of the present invention comprises: a paper substrate; a gate disposed on the paper substrate; a gate insulating layer containing silk protein, which is disposed on the paper substrate and covers the gate; an organic semiconductor layer; and a source and a drain, wherein the organic semiconductor layer, the source and the drain are disposed over the gate insulating layer.

### BACKGROUND OF THE INVENTION

1. Field of the Invention

The present invention relates to an organic thin film transistor (OTFT) and a method for manufacturing the same and, more particularly, to an OTFT and method for manufacturing the same which use paper as a substrate and silk protein as an insulating material. Therefore, the OTFT of the present invention has the characteristics of flexibility and rollablity due to use of the paper substrate.

2. Description of Related Art

Thin film transistors (TFTs) are fundamental components in contemporary electronics, such as sensors, radio frequency identification (RFID) tags, and electronic display devices. In recent years, in order to reduce the production cost and increase the product application, organic thin film transistors (OTFTs) have been rapidly developed which have the advantages of low-cost and flexibility, and can be produced in large-area.

The OTFTs can be divided into top contact OTFTs and bottom contact OTFTs. As shown in FIG. 1A, the top contact OTFT comprises: a substrate 10; a gate electrode 11 disposed on the substrate 10; a gate insulating layer 12 disposed on the substrate 11 and covering the gate electrode 11; an organic semiconductor layer 13 covering the entire surface of the organic semiconductor layer 12; and a source electrode 14 and a drain electrode 15 disposed on the organic semiconductor layer 13 respectively.

In addition, as shown in FIG. 1B, the bottom contact OTFT comprises: a substrate 10; a gate electrode 11 disposed on the substrate 10; a gate insulating layer 12 disposed on the substrate 10 and covering the gate electrode 11; a source electrode 14 and a drain electrode 15 disposed on the gate insulating layer 12 respectively; and an organic semiconductor layer 13 covering the gate insulating layer 12, the source electrode 14, and the drain electrode 15.

In the conventional method for forming the gate insulating layer, the dielectric material is sputtered on the substrate and the gate electrode to form the gate insulating layer. However, the instrument for the sputtering process is very expensive and the process is complex. In addition, the most suitable material conventionally used in the organic semiconductor layer of the OTFT is a pentacene. However, pentacene cannot match well with the conventional dielectric material, so the carrier mobility of pentacene is low. For example, when silicon nitride is used as a material of the gate insulating layer in the pentacene OTFT, the carrier mobility of the pentacene is lower than 0.5 cm²/V-sec. Even though aluminum nitride, which is generally known as a better material than the silicon nitride for the gate insulating layer in the pentacene OTFT, is used, the carrier mobility of the pentacene cannot be higher than 2 cm²/V-sec. Hence, it is impossible to manufacture OTFTs with high performance by using the present techniques and materials.

Recently, the environmental protection has become a global issue and attracts attention of the public worldwide. Although the plastic substrate can be used to form an OTFT with flexibility and rollabiltiy, it has the disadvantages of difficulty in recycling and causing environmental pollution. In order to meet the requirement of the environmental consciousness, an OTFT with a paper substrate is developed. However, when the paper substrate is used, the carrier mobility of the OTFT is low due to the restriction on the temperature of the process and the selection of the dielectric material. For example, Florian Eder et al. developed a pentacene OTFT with paper as a substrate and polyvinylphenol (PVP) as a dielectric material in 2004 (Applied Physics Letters 84, 2673-2675 (2004)), but the carrier mobility of the pentacene is only 0.2 cm²/V-sec.

Hence, it is desirable to develop an OTFT and a method for manufacturing the same by use of a paper substrate, in order to meet the requirement of the environmental consciousness, produce OTFTs with flexibility and rollability, and increase the transistor characteristics thereof.

### SUMMARY OF THE INVENTION

The object of the present invention is to provide an OTFT and a method for manufacturing the same to prepare an OTFT with flexibility, rollability and high performance.

To achieve the object, the OTFT of the present invention comprises: a paper substrate; a gate electrode disposed on the paper substrate; a gate insulating layer disposed on the paper substrate and covering the gate electrode, wherein the gate insulating layer comprises silk protein; an organic semiconductor layer; and a source electrode and a drain electrode, wherein the organic semiconductor layer, the source electrode, and the drain electrode are disposed over the gate insulating layer.

In addition, the present invention also provides a method for manufacturing the aforementioned OTFT, which comprises the following steps: (A) providing a paper substrate; (B) forming a gate electrode on the paper substrate; (C) coating the paper substrate having the gate electrode formed thereon with a silk solution to obtain a gate insulating layer on the paper substrate and the gate electrode; and (D) forming an organic semiconductor layer, a source electrode, and a drain electrode over the gate insulating layer.

According to the OTFT and the method for manufacturing the same of the present invention, the paper substrate with a gate electrode formed thereon is coated with a silk solution to form a gate insulating layer containing silk protein. Compared to the conventional method for forming the gate insulating layer through a sputtering process or a vacuum deposition process, the method of the present invention can be performed in a solution process. Hence, the process of the present invention is low cost and simple, and can be used for preparing the OTFT with large area. Also, the silk protein is low cost and easily available. In addition, the silk protein used in the OTFT of the present invention matches well with the material of the organic semiconductor layer, so the transistor characteristics of the OTFT can be greatly improved. Furthermore, paper, which is inexpensive and can be easily accessible, is used as a substrate, so the resulting OTFT has the advantages of flexibility, rollability, and foldability. Hence, the OTFT of the present invention can be applied to various fields, such as RFID. Also, the paper is an organic material which can be easily recycled. Compared to the OTFT with a plastic substrate, the environmental pollution can be solved by use of the OTFT of the present invention.

According to the OTFT and the method for manufacturing the same of the present invention, the silk protein may be natural silk protein. Preferably, the silk protein is fibroin. In addition, according to the OTFT and the method for manufacturing the same of the present invention, the silk solution may be an aqueous solution containing natural silk protein. Preferably, the silk solution is an aqueous solution containing fibroin.

According to the OTFT and the method for manufacturing the same of the present invention, the step (C) for coating the silk solution may further comprise the following steps: (C1) providing a silk solution; (C2) coating the paper substrate having the gate electrode formed thereon with the silk solution; and (C3) drying the silk solution coated on the paper substrate and the gate electrode to obtain a gate insulating layer on the paper substrate and the gate electrode. Hence, according to the OTFT and the method for manufacturing the same of the present invention, the silk film, which is used as a gate insulating layer, can be easily formed through simple coating and drying processes. Herein, the drying process can be any conventional drying method, such as an air-drying process or a baking process. When the step (C) for coating the silk solution is performed one time, the silk film with a single-layered structure is obtained. Also, the step (C) can be repeated to form the silk film with a multi-layered structure, if it is needed. In addition, the step (C2) is: applying the silk solution in droplets onto the paper substrate to coat the paper substrate having the gate electrode formed thereon with the silk solution, preferably.

Furthermore, according to the OTFT and the method for manufacturing the same of the present invention, the material of each electrode containing the gate electrode, the source electrode, and the drain electrode may be independently selected from the group consisting of Cu, Cr, Co, Ni, Zn, Ag, Pt, Au, and Al.

According to the OTFT and the method for manufacturing the same of the present invention, the material of the organic semiconductor layer may comprise pentacene, and other suitable materials. Preferably, the material of the organic semiconductor layer is pentacene.

Also, according to the method for manufacturing the OTFT of the present invention, the organic semiconductor layer covers the entire surface of the gate insulating layer, and the source electrode and the drain electrode are formed on the organic semiconductor layer to obtain a top contact organic thin film transistor, in the step (D).

In addition, according to the method for manufacturing the OTFT of the present invention, the source electrode and the drain electrode are formed on the gate insulating layer, and the organic semiconductor layer covers the source electrode, the drain electrode, and the gate insulating layer to obtain a bottom contact organic thin film transistor, in the step (D).

### BRIEF DESCRIPTION OF THE DRAWINGS

FIG. 1A is a perspective view of a conventional top contact OTFT;

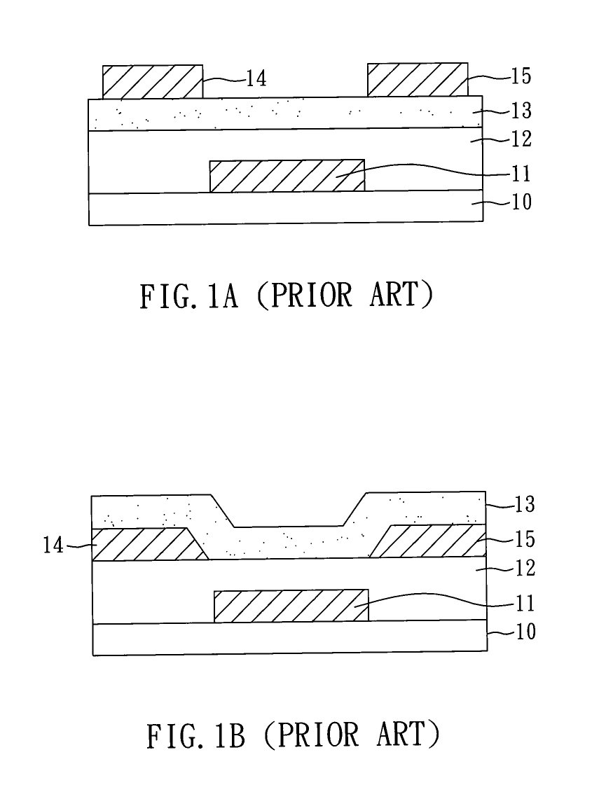

FIG. 1B is a perspective view of a conventional bottom contact OTFT; FIGS. 2A to 2D are cross-sectional views illustrating the process for manufacturing a top contact OTFT in Embodiment 1 of the present invention;

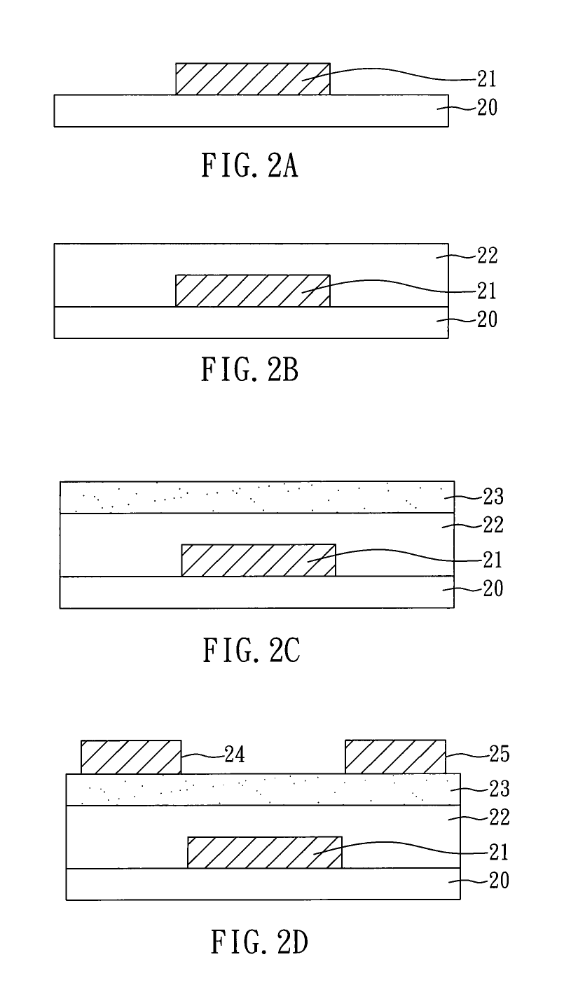

FIG. 3 is a graph curve showing the transfer characteristic of the OTFT of Embodiment 1 of the present invention;

FIG. 4 is a graph curve showing the output characteristic of the OTFT of Embodiment 1 of the present invention; and

FIGS. 5A to 5C are cross-sectional views illustrating the process for manufacturing a bottom contact OTFT in Embodiment 2 of the present invention

### DETAILED DESCRIPTION OF THE PREFERRED EMBODIMENT

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

### Embodiment 1

### Top Contact OTFT

### [Preparation of a Silk Solution]

First, 10 wt % of an aqueous solution of Na₂CO₃ was provided and heated. When the solution was boiling, silkworm cocoon (natural silk) was added thereto, and the solution was kept boiling for 30 min to remove sericin. Then, the silk without sericin was washed by deionized water to remove the alkali salt adhered on the silk. After a drying process, refined silk, i.e. fibroin, was obtained.

Next, the refined silk was added into 85 wt % of phosphoric acid (H₃PO₄) solution (20 ml), and the resulted solution was stirred until the refined silk was dissolved. Then, the phosphoric acid solution containing the refined silk was put into a membrane (Spectra/Por 3 membrane, molecular weight cutoff=14000) and dialyzed with water. The dialysis process was performed for 3 days to remove the phosphate ions. After the dialysis process is completed, a filter paper is used to filter out impurities, and an aqueous solution of fibroin is obtained.

### [Preparation of a Top Contact OTFT]

As shown in FIG. 2A, a paper substrate 20 was provided. Then, the paper substrate 20 was placed inside a vacuum chamber (not shown in the figure), and a metal was evaporated on the paper substrate 20 by using a mask (not shown in the figure) to form a patterned metal layer, which was used as a gate electrode 21, as shown in FIG. 2A. In the present embodiment, the metal used in the gate electrode 21 was Au, and the thickness of the gate electrode 21 was about 80 nm. In addition, the condition of the evaporation process for forming the gate electrode 21 is listed below.
Pressure: 5×10⁻⁶ torr
Evaporation rate: 1 Å/s

Next, the aforementioned silk solution was applied in droplets on the paper substrate 20 having the gate electrode 21 formed thereon to coat the paper substrate 20 having the gate electrode 21 with the silk solution. The paper substrate 20 was allowed to stand for 15 min, and then it was shaken to remove the redundant solution. The paper substrate 20 coated with the silk protein was dried at 60° C. to form a silk film, and the silk film was used as a gate insulating layer 22, as shown in FIG. 2B. In the present embodiment, the gate insulating layer 22 formed by the silk film has a thickness of 400 nm. In addition, the coating process and the drying process can be performed several times to form a silk film with multi-layered structure.

As shown in FIG. 2C, through a heat evaporation process, pentacene was deposited on the gate insulating layer 22 at room temperature by use of a shadow metal mask to form an organic semiconductor layer 23. In the present embodiment, the thickness of the organic semiconductor layer 23 is about 70 nm. In addition, the condition of the heat evaporation process for forming the organic semiconductor layer 23 is listed below.
Pressure: 2×10⁻⁶ torr
Evaporation rate: 0.3 Å/s

Finally, the same evaporation process for forming the gate electrode was performed to form a patterned metal layer, which was used as a source electrode 24 and a drain electrode 25, on the organic semiconductor layer 23 by using another mask (not shown in the figure), as shown in FIG. 2D. In the present embodiment, the material of the source electrode 24 and the drain electrode 25 was Au, and the thickness of source electrode 24 and the drain electrode 25 was about 80 nm.

As shown in FIG. 2D, after the aforementioned process, a top contact OTFT of the present embodiment was obtained, which comprises: a paper substrate 20; a gate electrode 21 disposed on the paper substrate 20; a gate insulating layer 22 disposed on the substrate 20 and covering the gate electrode 21, wherein the gate insulating layer 22 comprises silk fibroin; an organic semiconductor layer 23 covering the entire surface of the gate insulating layer 22; and a source electrode 24 and a drain electrode 25, respectively disposed on the organic semiconductor layer 23.

### [Evaluation of the Characteristics of the OTFT]

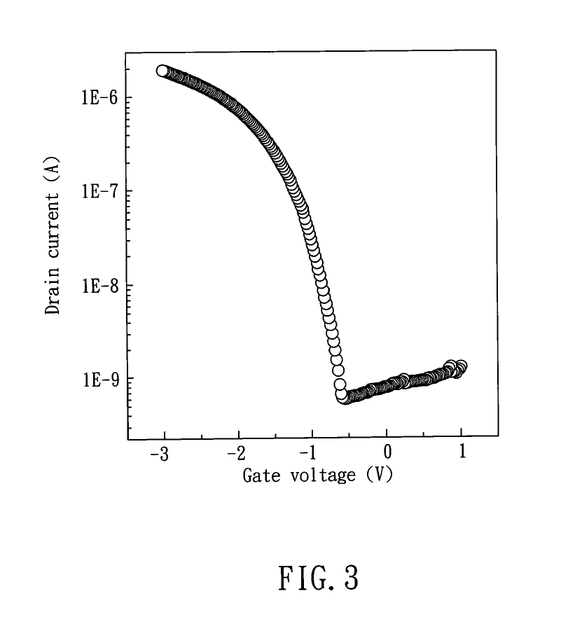

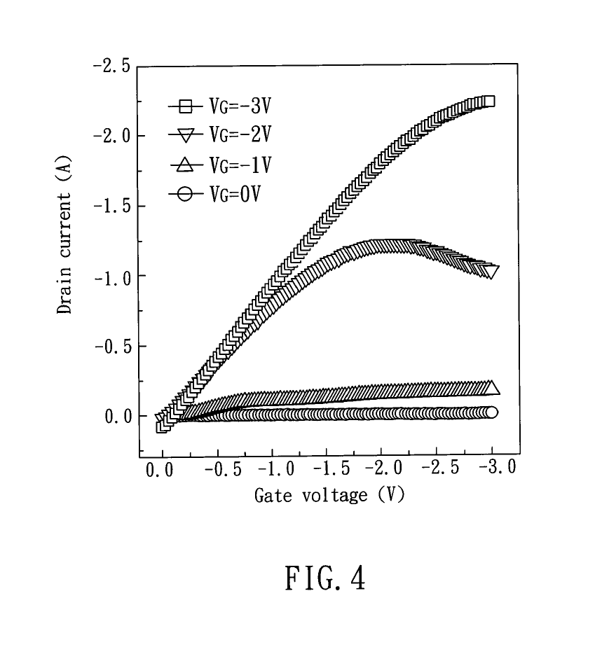

A current-voltage test was performed on the top contact OTFT of the present embodiment. The result of the transfer characteristic of the OTFT is shown in FIG. 3, and the result of the output characteristic under different gate voltage (V_{G}) is shown in FIG. 4. The current on-to-off ratio (I_{ON/OFF}), the subthreshold swing (S.S), the carrier mobility and the threshold voltage (V_{TH}) are listed in the following Table 1.

TABLE 1

| | Results | |
|---|---|---|
| Channel width | 600 | μm |
| Channel length | 75 | μm |
| Thickness of the gate insulating layer | 400 | nm |
| Thickness of the organic semiconductor layer | 70 | nm |
| I_{ON/OFF} | 3.2 × 10⁴ | |
| S.S | 172 mV/decade | |
| Carrier mobility | 14.13 cm²/V-sec | |
| V_{TH} | −0.77 | V |

According to the results shown in FIG. 3, FIG. 4 and Table 1, the carrier mobility of the gate insulating layer made of the silk protein is about 14 cm²/V-sec. Compared to the conventional pentacene OTFT with a gate insulating layer made from silicon nitride or aluminum nitride, the device performance of the pentacene OTFT of the present embodiment can be improved greatly, due to use of the silk protein as a dielectric material of the gate insulating layer.

In addition, the paper substrate used in the OTFT of the present embodiment is inexpensive and easily accessible. Compared to the OTFT with a plastic substrate, the OTFT of the present embodiment has not only the property of flexibility and rollability, but also the property of foldability.

### Embodiment 2

### Bottom Contact OTFT

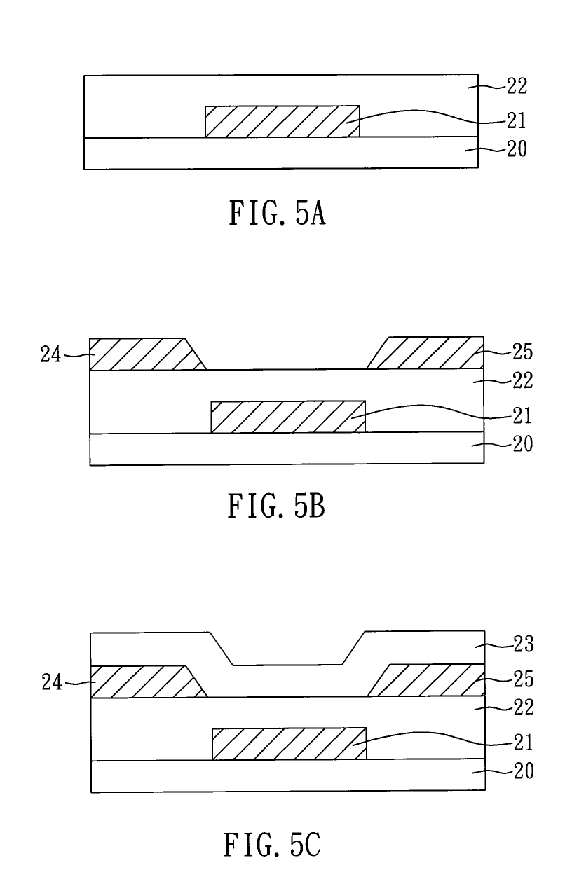

As shown in FIG. 5A, a paper substrate 20 was provided, and a gate electrode 21 and a gate insulating layer 22 was formed on the paper substrate 20 sequentially. In the present embodiment, the preparing methods and the materials of the paper substrate 20, the gate electrode 21, and the gate insulating layer 22 are the same as those illustrated in Embodiment 1. In addition, in the present embodiment, the thickness of the gate electrode 21 was about 100 nm, and the thickness of the gate insulating layer 22 was about 500 nm.

Next, the evaporation process was performed on the gate insulating layer 22 to form a patterned metal layer through the same evaporation process for forming the gate electrode described in Embodiment 1, wherein the patterned metal layer was used as a source electrode 24 and a drain electrode 25, as shown in FIG. 5B. In the present embodiment, the material of the source electrode 24 and the drain electrode 25 was Au, and the thickness of the source electrode 24 and the drain electrode 25 was about 100 nm.

Finally, an organic semiconductor layer 23 was formed on the gate insulating layer 22, the source electrode 24, and the drain electrode 25 through the same process for forming the organic semiconductor layer described in Embodiment 1, as shown in FIG. 5C. In the present embodiment, the material of the organic semiconductor layer 23 is pentacene, and the thickness of the organic semiconductor layer 23 is about 100 nm.

As shown in FIG. 5C, after the aforementioned process, a bottom contact OTFT of the present embodiment was obtained, which comprises: a paper substrate 20; a gate electrode 21 disposed on the paper substrate 20; a gate insulating layer 22 disposed on the paper substrate 20 and covering the gate electrode 21, wherein the gate insulating layer 22 comprises silk fibroin; a source electrode 24 and a drain electrode 25 respectively located on the gate insulating layer 22; and an organic semiconductor layer 23 covering the gate insulating layer 22, the source electrode 24, and the drain electrode 25.

In conclusion, according to the OTFT and the method for manufacturing the same of the present invention, the silk fibroin is used as a dielectric material, and the gate insulating layer is formed through a solution process. Hence, the complexity of the process and the production cost can be greatly decreased. Also, the process of the present invention can be used to form the OTFT with large area. In addition, the carrier mobility of pentacene in the OTFT can be increased greatly due to use of the silk fibroin as the material of the gate insulating layer. Furthermore, the paper substrate used in the OTFT of the present invention is easily accessible and inexpensive. Also, the OTFT of the present invention is flexible and rollable, so it can be applied on various electronic devices. In addition, the paper substrate and the silk film are natural organic material and can be easily recycled, so the environmental protection can also be achieved.

Although the present invention has been explained in relation to its preferred embodiment, it is to be understood that many other possible modifications and variations can be made without departing from the scope of the invention as hereinafter claimed.

What is claimed is:

1. An organic thin film transistor, comprising:
a paper substrate;
a gate electrode disposed on the paper substrate;
a gate insulating layer disposed on the paper substrate and covering the gate electrode, wherein the gate insulating layer comprises silk protein;
an organic semiconductor layer; and
a source electrode and a drain electrode,
wherein the organic semiconductor layer, the source electrode, and the drain electrode are disposed over the gate insulating layer.

2. The organic thin film transistor as claimed in claim 1, wherein the silk protein is natural silk protein.

3. The organic thin film transistor as claimed in claim 1, wherein the silk protein is fibroin.

4. The organic thin film transistor as claimed in claim 1, wherein the gate insulating layer has a single-layered structure or a multi-layered structure.

5. The organic thin film transistor as claimed in claim 1, wherein the material of the organic semiconductor layer comprises a pentacene.

6. The organic thin film transistor as claimed in claim 1, wherein the organic semiconductor layer covers the entire surface of the gate insulating layer, and the source electrode and the drain electrode respectively locate on the organic semiconductor layer, when the organic thin film transistor is a top contact organic thin film transistor.

7. The organic thin film transistor as claimed in claim 1, wherein the source electrode and the drain electrode respectively locate on the gate insulating layer, and the organic semiconductor layer covers the gate insulating layer, the source electrode, and the drain electrode when the organic thin film transistor is a bottom contact organic thin film transistor.

8. A method for manufacturing an organic thin film transistor, comprising the following steps:
(A) providing a paper substrate;
(B) forming a gate electrode on the paper substrate;
(C) coating the paper substrate having the gate electrode formed thereon with a silk solution to obtain a gate insulating layer on the paper substrate and the gate electrode; and
(D) forming an organic semiconductor layer, a source electrode, and a drain electrode over the gate insulating layer.

9. The method as claimed in claim 8, wherein the step (C) comprises the following steps:
(C1) providing a silk solution;
(C2) coating the paper substrate having the gate electrode formed thereon with the silk solution; and
(C3) drying the silk solution coated on the paper substrate and the gate electrode to obtain a gate insulating layer on the paper substrate and the gate electrode.

10. The method as claimed in claim 9, wherein the step (C2) is: applying the silk solution in droplets onto the paper substrate to coat the paper substrate having the gate electrode formed thereon with the silk solution.

11. The method as claimed in claim 8, wherein the silk solution is an aqueous solution containing natural silk protein.

12. The method as claimed in claim 8, wherein the silk solution is an aqueous solution containing fibroin.

13. The method as claimed in claim 8, wherein the material of the organic semiconductor layer comprises a pentacene.

14. The method as claimed in claim 8, wherein the organic semiconductor layer covers the entire surface of the gate insulating layer, and the source electrode and the drain electrode are formed on the organic semiconductor layer to obtain a top contact organic thin film transistor, in the step (D).

15. The method as claimed in claim 8, wherein the source electrode and the drain electrode are formed on the gate insulating layer, and the organic semiconductor layer covers the source electrode, the drain electrode, and the gate insulating layer to obtain a bottom contact organic thin film transistor, in the step (D).
